(19) United States
(12) Patent Application Publication
(10) Pub. No.: US 2025/0391709 A1
(43) Pub. Date: Dec. 25, 2025

(54) SAMPLE PREPARATION FOR CHARGED PARTICLE BEAM IMAGING

(71) Applicant: Carl Zeiss SMT GmbH, Oberkochen (DE)

(72) Inventors: Lakshmi Sravani MANTHA, Aalen (DE); Thomas KORB, Schwaebisch Gmuend (DE); Hyun Hwa KIM, Huettlingen (DE)

(21) Appl. No.: 19/309,996

(22) Filed: Aug. 26, 2025

Related U.S. Application Data
(63) Continuation of application No. PCT/EP2024/055854, filed on Mar. 6, 2024.

(30) Foreign Application Priority Data
Mar. 7, 2023 (DE) 10 2023 105 604.2

(51) Int. Cl. H01L 21/66; H01J 37/28; H01J 37/305; H01L 21/263

(52) U.S. Cl. CPC H01L 22/12; H01J 37/28; H01J 37/3053; H01L 21/2633; H01J 2237/2817

(57) ABSTRACT

A method of preparing a sample for charged particle beam inspection comprises providing a semiconductor structure sample and identifying electrically isolated regions in an area of the sample to be examined. The method further comprises providing an electrical connection to the at least one electrically isolated region.

### CROSS-REFERENCE TO RELATED APPLICATIONS

The present application is a continuation of, and claims benefit under 35 USC 120 to, international application No. PCT/EP2024/055854, filed Mar. 6, 2024, which claims benefit under 35 USC 119 of German Application No. 10 2023 105 604.2, filed Mar. 7, 2023. The entire disclosure of each of these applications is incorporated by reference herein.

### FIELD

Various examples of this disclosure pertain to techniques of sample preparation of semiconductor structures for charged particle beam imaging, for example scanning electron microscopy (SEM) imaging, and to inspecting semiconductor structures by charged particle beam imaging.

### BACKGROUND

With the continuous development of ever smaller and ever more complex microstructures such as semiconductor components, there is a desire to develop and optimize inspection systems for inspecting small dimensions of the microstructures. The development and production of the semiconductor components generally involves high resolution metrology tools with high throughput. Also, production techniques for such semiconductor components generally involve corresponding process monitoring.

One approach for inspecting semiconductor structures of such components is scanning electron microscopes (SEMs), where a surface of a sample is scanned with an electron beam. For increasing the throughput, multi beam scanning electron microscopes (MSEMs) have been used which use multiple electron beams for scanning. Such MSEMs are for example described in U.S. Pat. No. 7,244,949 B2 and in US 2019/0355544 A1. Other charged particle beams than electron beams, e.g. ion beams, may also be used.

Recently, 3D volume image generation has been introduced. 3D volume images are generated via a cross-section slicing techniques, utilizing a charged particle beam system to slice and image an integrated semiconductor structure to determine a 3D volume image of a predetermined volume within the semiconductor structure. Such a cross-section imaging technique includes the generation and storing of a large set of 2D cross-section images and the registration of the 2D cross-section images within a volume to generate a 3D volume image of high precision. The charged particle system can comprise a scanning electron microscope (SEM) for imaging and a focused ion beam system (FIB) for slicing, or an ion beam system for slicing and imaging. One type of structures which may be imaged in this way are three-dimensional structures (as opposed to planar geometries) like 3D NAND memory chips and other high aspect ratio structures (HAR). 3D Imaging of such NAND memory chips and other high aspect ratio structures is described in detail in WO 2022/223 229 A1, which is incorporated by reference herein. In the inspection process, surfaces with areas to be examined may be prepared using ion milling by the FIB system (slicing). These surfaces may be slanted with respect to a surface of the semiconductor structure in a wedge-like configuration. This approach will also be referred to as wedge-cut herein. The areas to be examined are then inspected using the SEM (imaging). The slicing and imaging are repeated to obtain a 3D (volume) image. For example, a plurality of cross-section surfaces is subsequently milled by focused ion beam milling with an ion beam parallel to each newly formed cross section surface, and a plurality of two-dimensional images are acquired by scanning electron beam imaging of each newly revealed cross section. Each cross-section surface comprises cross sections with vertical structures such as HAR (high aspect ratio) structures of a memory device, and cross sections with the many layers of a multilayer stack.

When scanning the surface of the semiconductor structure with a charged particle beam, the surface may be charged. These charges may disturb the imaging. While this effect is deliberately used for some analysis methods, like the examination of a semiconductor structures for broken electrical connections, in other circumstances this effect may lead to a deterioration of image quality and thus for example to imprecise measurements of structure sizes.

US 2020/402 813 A1 describes an end-pointing during delayering. Delayering with ion beam assisted etching perpendicular to a wafer surface is relatively sensitive and for example charges may have a deteriorating effect on the delayering and/or on measurement ensuring that the delayering is performed to a desired depth. Proper end-pointing during delayering is often used for applications such as circuit edit. This is not an issue with ion beam sputtering in the above-described wedge cut-configuration. Here, the ion beam is oriented parallel to a cross-section surface to be generated and sputtering per se generates a smooth surface. In general, charging is not a big issue for ion beam sputtering.

Some applications use a charged particle beam for imaging of insulators. According to JP H08-138 617 A, a conductive layer is formed at the irradiation region of the insulator with an ion beam. The conductive probe can be brought into contact with conductive layer, and charging of the insulator is reduced.

During ion beam milling, for example for TEM lamella preparation, particles sputtered away by the ion beam may form a layer of debris around a milling area. Deposition of protective coatings to protect a surface of a sample is known. For example, US 2008/073 587 A1 proposes using a sputter coat on a surface, forming a protective or conductive coating. The sample with the sputter coating is subsequently processed by ion beam milling.

During scanning electron beam inspection of samples, such as a semiconductor mask or a wafer, the sample might generally charge up due to the exposure to the electron beam. Therefore, samples are generally electrically connected to a specific potential such as ground. Connecting mask or wafer samples to ground might involve forming an access to conducting layers of the mask or wafer sample. Some examples of electrically connecting of a mask or wafer sample are illustrated in US 2023/005 698 A1.

Local charging might arise at insulating material and has a deteriorating effect on the imaging of an insulator with an electron beam. Therefore, different methods to remove surface charges formed at insulating material such as photoresist have been proposed. For example, U.S. Pat. No. 5,512,746 proposes using a probe for removing electrons from a surface of an insulating material. U.S. Pat. No. 4,991,661 proposes depositing an electrically conductive film only on a part of the surface of a specimen and thereby removing charges. According to U.S. Pat. No. 5,512,746, however, deposition of a metal thin film over a measurement object can cause contamination and is improper for in-line measurement of micro patterns.

The methods discussed above do not generally provide a solution for the slice-and image method using a FIB for ion milling and another beam like an electron beam of a SEM for inspection, for example in a dual beam device, for forming a plurality of cross-section images at a slanted angle through a multi-layer stack within a semiconductor wafer as described above.

Since surface charges generated at insulating material are removed after each milling step, surface charges at insulators are typically not a big issue. On the other hand, however, alternating layers of the multilayer stack may comprise structures formed of conducting material and isolated capacities may be formed within some of the layers. Charges may be slowly accumulated within these isolated conducting structures over a series of image acquisitions with the SEM, comprising for example more the 100 image acquisitions, for example up to 1000 image acquisitions.

A deteriorating electrical field is generally proportional to an accumulated charge Q divided by the capacity C of an insulated conductor (U˜Q/C). Many small and different capacities with different charges and therefore many different electrical fields may thus be formed at a cross section through a multi-layer stack. In addition to the deteriorating effect of local fields on a secondary of backscattered electron yield, the different fields can also introduce lateral field gradients, which can introduce significant distortion especially during scanning charged particle beam imaging with electrons of low momentum.

### SUMMARY

Some techniques disclosed herein may help to reduce charging effects during the inspection of semiconductor samples, and thus in some implementations may lead to an improved image quality, improved measurement results or both.

In an aspect, the disclosure provides a method for inspecting a semiconductor structure sample is provided. The method comprises providing a semiconductor structure sample, ion beam milling the semiconductor structure sample to form a slanted surface under an angle with respect to a surface of the semiconductor structure sample, wherein the ion beam milling causes formation of at least one electrically isolated region in an area of the semiconductor structure sample to be examined, and providing an electrical connection to the at least one electrically isolated region. The method further comprises performing a charged particle beam inspection of the area to be examined.

By providing the electrical connection, charge accumulating in the at least one electrically isolated region can flow away from the region, which may mitigate charging effects when inspecting the semiconductor structure sample with a charged particle inspection method like scanning electron microscopy.

The angle between the surface of the semiconductor structure sample and the slanted surface may for example be between 10° and 30° when measured as acute angle between the planes in which the surface of the semiconductor structure sample and the slanted surface lie, respectively.

It should be noted that the electrical connection provided is not part of the semiconductor structure sample to be examined per se, but is specifically added for the purpose of inspection.

It should be noted that the electrical connection may be provided before or after the ion beam milling. In the former case (before the ion beam milling), the forming of the electrically isolated areas above is to be understood that in the absence of the electrical connection, such isolated areas would be formed.

The term semiconductor structure sample does not exclude the presence of materials other than semiconductors. For example, the semiconductor structure sample may include structured or unstructured metal layers, structured or unstructured dielectric layers or other layers and materials common in semiconductor devices.

In some examples, providing the electrical connection comprises providing the electrical connection outside the area to be examined. In this way, the inspection is not disturbed by the electrical connection, and the complete area to be examined may be actually inspected.

In some examples, providing the electrical connection may include depositing a conducting material, for example a metal like platinum or tungsten, in a trench formed in the semiconductor structure sample. In this way, the electrical connection may be formed using standard semiconductor technologies or at least in part a semiconductor charged particle inspection device. For example, in a device as explained in the introductory portion, the trench may be formed using a focused ion beam (FIB).

The method may comprise identifying the at least one electrically isolated region. Identifying the at least one electrically isolated region in the area to be examined may be based on knowledge about the semiconductor structure sample. Usually, the semiconductor structure sample has a known nominal structure, i.e. is designed to have a specific structure, which is reflected in design data. Based on this design data, the at least one electrically isolated region may be identified.

While in some examples this identifying may be performed by an operator by looking at the design of the semiconductor structure sample, in other examples this may be performed automatically, or by an operator supported by automatic analysis.

As mentioned, the nominal semiconductor structure sample is usually known by design data. Furthermore, the electrical network formed by the semiconductor structure sample is also usually known—semiconductor structures are designed to have a certain electrical function, and commercially available tools for chip design provide a mapping between the two. By a connectivity analysis also offered by commercial semiconductor design software, electrically isolated regions may be found. When material is removed for preparing the area to be examined by the ion beam milling, corresponding portions of the electrical network may also be removed, and again a connectivity analysis may identify the at least one electrically isolated region. A location of the electrical connection may also be proposed with corresponding design software, for example by searching for a cuboid space (which is the filled with conducting material to form the electrical connection) connecting the at least one electrically isolated region.

In some examples, the at least one electrically isolated region may include a plurality of electrically isolated regions, and the electrical connection may connect the plurality of electrically isolated regions with each other. In this way, charge between the electrically isolated regions may be balanced. According to an embodiment of the disclosure, by forming the at least one electrical connection local isolated capacities are interconnected, and larger capacities are formed. Thereby, local large fields of small capacities may be removed. By interconnecting of many capacities, at least one large capacity may be formed. Thereby, also local differences in fields and lateral field gradients may be balanced out and removed. According to an embodiment of the disclosure, alone the interconnecting structure increases a capacity significantly, thereby even more reducing an electrical field generated by the increased capacity (U˜Q/C).

In embodiments, additionally or alternatively the electrical connection may electrically connect the at least one electrically isolated region to a reference potential like ground and/or to a semiconductor substrate, such that charge may flow away from the at least electrically isolated region.

As mentioned above, the method comprises preparing the area to be examined by removing material from the semiconductor structure sample in a wedge form with a focused ion beam, which may be used to provide 3D imaging of the semiconductor sample. In such a case, the electrical isolation of the at least one electrical isolated region may be caused by the preparation of the area to be examined, i.e., the material removal. In other words, by removing material to prepare the area to be examined, a previously electrically non-isolated region may become an electrically isolated region. Also here, as it may be planned in advance how the area to be examined is prepared, the identifying may be performed based on this advanced knowledge. It should be noted that preparing the area to be examined may be performed before or after the providing of the electrical connection. The ion beam milling and the inspection may be repeated several times to obtain a 3D image. In some examples, the at least one electrical connection provides an electrical connection to otherwise isolated regions for a plurality of the slanted surfaces formed through the repeating.

In some examples, the semiconductor structure sample may include a 3D NAND memory structure. Such structures include slits isolating channel banks from each other. Depending on the preparation of the area to be examined, such channel banks may then correspond to electrically isolated regions.

In some examples, a method is provided which comprises preparing a semiconductor structure sample for charged particle beam inspection as by any one of the above methods, and inspecting the prepared sample with a charged particle beam.

In an aspect, a corresponding sample inspection apparatus is configured to provide an electrical connection to at least one electrically isolated region in an area to be examined of a semiconductor structure sample. The apparatus comprises a focused ion beam device and a charged particle beam inspection device like a scanning electron microscope.

### BRIEF DESCRIPTION OF THE DRAWINGS

FIG. 1 is a flowchart illustrating a method according to an embodiment.

FIG. 2 is a block diagram of a system according to an embodiment.

FIGS. 3A-3C illustrate 3D NAND semiconductor structures.

FIGS. 4A and 4B illustrate the effect of charging.

FIG. 5 is a perspective view of a semiconductor structure sample according to an embodiment.

FIGS. 6A and 6B are views of a semiconductor structure sample for illustrating the effect of embodiments.

FIGS. 7A and 7B are views illustrating the formation of an electrical connection.

FIG. 8 shows SEM measurements for illustrating the effects of some embodiments.

FIG. 9 shows an inspection device according to some embodiments.

FIG. 10. is a diagram illustration sample preparation according to some embodiments.

FIGS. 11A and 11B illustrate charge accumulation.

FIG. 12 illustrates formation of an electrical connection.

FIGS. 13A to 13C further illustrate processing of semiconductor sample structures according to some embodiments.

### DETAILED DESCRIPTION

In the following, embodiments will be described with a level of detail with reference to the accompanying drawings. It is to be understood that the following description of embodiments is not to be taken in a limiting sense. The scope of the application is not intended to be limited by the embodiments described hereinafter or by the drawings, which are taken to be illustrative only.

The drawings are to be regarded as being schematic representation and elements illustrated in the drawings are not necessarily shown to scale. Rather, the various elements are represented such as a function in general purpose becomes apparent to a person skilled in the art. Any connection or coupling between functional blocks, devices, components or other physical or functional units shown in the drawings or described herein may also be implemented by an indirect connection or coupling. Functional blocks may be implemented in hardware, firmware, software or a combination thereof.

In some of the embodiments described hereinafter, 3D NAND memory structures will be used as an example for semiconductor structure samples to be examined. This is not to be construed as limiting, and techniques disclosed herein may be used generally for semiconductor structure samples to be examined by a charged particle beam technique, which include electrically isolated regions, either due to the structure of the sample itself or due to preparation of an area to be examined. Therefore, the example of 3D NAND memory structure is only given for illustration and better understanding. Furthermore, in the following scanning electron microscopy (SEM), for example MSEM, will be used as an example for a charged particle beam inspection technique, but other techniques, for example using charged ions instead of electrons as a beam, can also be used.

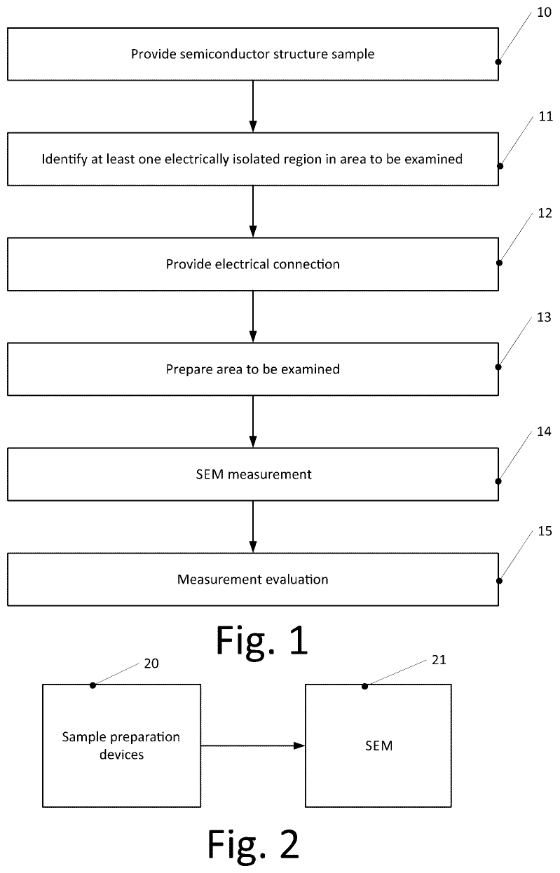

FIG. 1 illustrates a method according to some embodiments. At a step 10, the method comprises providing a semiconductor structure sample to be inspected using a charged particle beam technique.

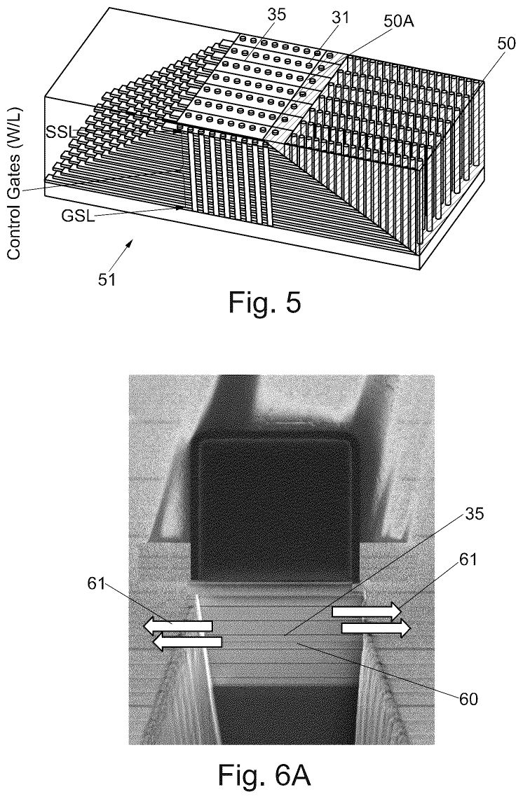

As an example, FIGS. 3A-3C illustrate a 3D NAND memory structure, which is an example for a semiconductor structure sample provided at step 10 of FIG. 1. FIGS. 3A and 3C show the 3D NAND structure in two different directions, and FIG. 3B shows a magnified portion of a channel bank forming a stripe 30 of FIG. 3A.

Generally, the 3D NAND memory structure includes pillars or channels 31 which have several layers as shown, and are coupled by word lines 32. Stripes 30 are separated by slits 35. Slits 35 provide an electrical isolation between adjacent stripes, which may lead to the formation of electrically isolated regions, depending on sample preparation. Numeral 34 denotes transition layers, and numeral 36 denotes bit lines. The transition layer in the example shown is due to the fact that two 3D NAND memory chips are stacked on top of each other for higher integration. The transition layer is used due to technological limits of the depth for controlled etching of the channels. More information regarding such structures may be found in the above mentioned WO 2022/223 229 A1.

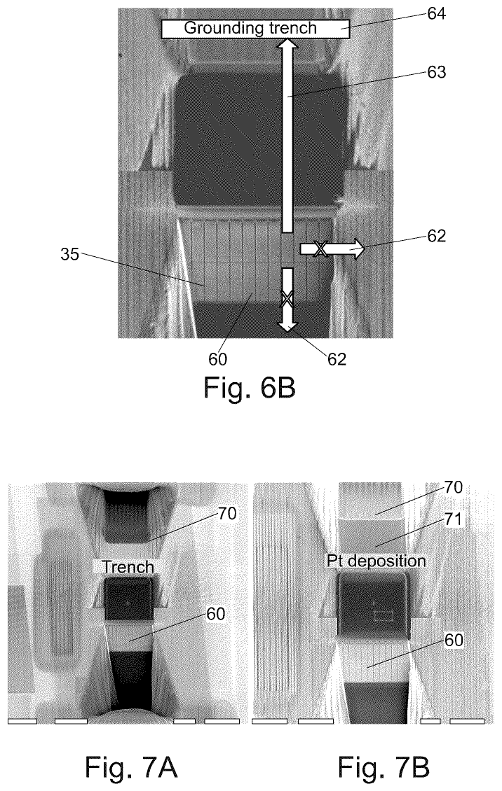

At step 11, the method of FIG. 1 comprises identifying electrically isolated regions in an area of the semiconductor sample to be examined. At step 12, the method comprises providing an electrical connection to the at least one electrically isolated region. At step 13, the method comprises preparing the area to be examined, for example by focused ion beam slicing. The identifying of the at least one electrically isolated region may be made taking the preparation of the area to be examined into account, i.e. in some examples it may be the preparation which leads to the formation of electrically isolated regions. The order of steps 11-13 need not be in the order shown in FIG. 1, but for example the preparation of the area to be examined in step 13 may be prior to the providing of the electrical connection at step 12. Examples for the various actions at steps 11-13 will now be explained referring to FIGS. 4 to 13 (including respective subfigures A, B, C where provided).

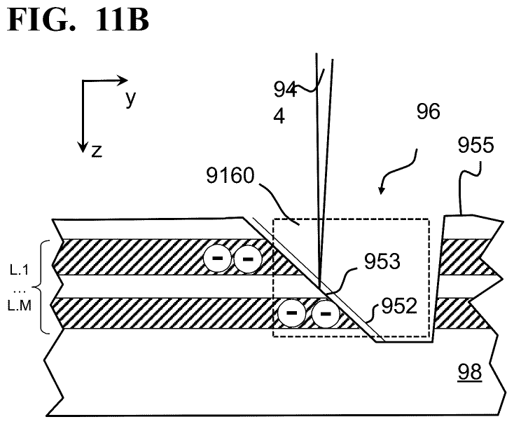

For the preparation in step 13 and a measurement described further below also with respect to step 14, for example for investigation of 3D inspection volumes in semiconductor wafers, a slice and imaging method may be used, which is applicable to inspection of volumes inside a wafer. In an example, a 3D volume image is generated from an inspection volume inside a wafer by the so called “wedge-cut” approach or wedge-cut geometry, without the need of a removal of a sample piece from the wafer. The slice and image method is applied to an inspection volume with dimensions of few μm, for example with a lateral extension of 5 μm to 10 μm in wafers with diameters of 200 mm or 300 mm. The lateral extension can also be larger and reach up to 30 or 50 micrometers. A V-shaped groove or edge is milled in the top surface of an integrated semiconductor wafer to make accessible a cross-section surface at an angle to the top surface. 3D volume images of inspection volumes are acquired at a limited number of inspection sites, for example representative sites of dies, for example at process control monitors (PCM), or at sites identified by other inspection tools. In general, the slice and image method will destroy the wafer only locally, and other dies may still be used, or the wafer may still be used for further processing. Methods and inspection systems according to the 3D Volume image generation are described in WO 2021/180600 A1, which is fully incorporated herein by reference. An example of a wafer inspection system 1000 for 3D volume inspection is illustrated in FIG. 9. The wafer inspection system 1000 is configured for a slice and imaging method under a wedge cut geometry with a dual beam device 91. For a wafer 98, inspection sites, comprising inspection sites 96.1 and 96.2, are defined in a location map or inspection list generated from an inspection tool or from design information. These inspection sites define the location of areas to be examined in the semiconductor structure sample, e.g. wafer 98 with structures formed thereon. The wafer 98 is placed on a wafer support table 915. The wafer support table 915 is mounted on a stage 9155 with actuators and position control. Actuators and mechanisms for precision control for a wafer stage such as Laser interferometers are known. A control unit 916 is configured to control the wafer stage 9155 and to adjust an inspection site 96.1 of the wafer 98 at the intersection point 943 of the dual-beam device 91. The dual beam device 91 comprises a FIB column 950 with a FIB optical axis 948 and a charged particle beam (CPB) imaging system 940 with optical axis 942. At the intersection point 943 of both optical axes of FIB and CPB imaging system, the wafer surface 955 is arranged at a slant angle GF to the FIB axis 948. FIB axis 948 and CPB imaging system axis 942 include an angle GFE, and the CPB imaging system axis forms an angle GE with the normal to the wafer surface 955. In the coordinate system of FIG. 9, the normal to the wafer surface 955 is given by the z-axis. The focused ion beam (FIB) 951 is generated by the FIB-column 50 and is impinging under angle GF on the surface 55 of the wafer 98. Slanted cross-section surfaces are milled into the wafer by ion beam milling at the inspection site 96.1 under approximately the slant angle GF. In the example of FIG. 9, the slant angle GF is approximately 30°. The actual slant angle of the slanted cross-section surface can deviate from the slant angle GF by up to 1° to 4° due to the beam divergency of the focused ion beam, for example a Gallium-Ion beam.

Generally, a FIB column 950 can for example be a Gallium FIB, with or without a Wien filter or similar mechanism to allow alloy-based sources (such as silicon, gold, etc.), or a FIB with a gas field ion source (GFIS), plasma source or duo-plasmatron with other kinds of ion species, such as Xenon, Oxygen or Argon ions or related technologies (for example “cluster” or “low temperature” ion sources). Generally, FIB column 950 is used to produce focused ion beams, optionally at different charge states of ions.

With the charged particle beam imaging system 940, inclined under angle GE to the wafer normal, images of the milled surfaces are acquired. In the example of FIG. 9, the angle GE is about 15°. However, other arrangements are possible as well, for example with GE=GF, such that the CPB imaging system axis 942 is perpendicular to the FIB axis 948 (and GFE=) 90°, or GE=0°, such that the CPB imaging system axis 942 is perpendicular to the wafer surface 955.

During imaging, a beam of charged particles 944 is scanned by a scanning unit of the charged particle beam imaging system 940 along a scan path over a cross-section surface of the wafer 98 at inspection site 96.1, and secondary particles as well as scattered particles are generated. For example, secondary electron particle detector 917.1 collects at least some of the secondary particles and scattered particles and communicates the particle count with a control unit 919. Other detectors for other of interaction products may be present as well, for example in-lens detector 917.2 for collection of backscattered electrons. Control unit 919 is in control of the charged particle beam imaging column 940, of FIB column 950 and connected to a stage control unit 916 to control the position of the wafer 98 mounted on the wafer support table 915 via the wafer stage 9155. Control unit 919 communicates with operation control unit 2, which triggers placement and alignment for example of inspection site 96.1 of the wafer 98 at the intersection point 943 via wafer stage movement and triggers repeatedly operations of FIB milling, image acquisition and stage movements.

Each new intersection surface is milled by the FIB beam 951, and imaged by the charged particle imaging beam 944, which is for example scanning electron beam.

The dual beam system 91 further comprises a gas injection system (GIS) 79, with a gas nozzle connected via a valve (not shown) to at least one gas reservoir (not shown). Thereby, controlled amounts of precursor gases can be provided during milling or imaging, and for example metal coatings can be generated. For example, alignment marks or fiducials can be generated. For example, a Tungsten metal coating is generated by providing Tungsten Hexacarbonyl. The metal coating can be shaped by ion beam milling and alignment markers or fiducials are formed in proximity to an inspection site. Thereby, a precise registration and image alignment of the plurality of cross section images is enabled. With dedicated precursor gases, a milling operation by FIB 51 can be enhanced. For example, a homogeneity of a milling operation in compositions of different material can be improved and curtaining can be reduced. Compositions of materials in a semiconductor wafer can comprise Silicon, Silicon Dioxide, Silicon Nitride, Copper, Aluminum, or other materials.

Examples of precursor gases comprise at least one of Ammonia, Ammonium Hydroxide, Ammonium Carbamate, Bromine, Chlorine, Hydrazine, Hydrogen Peroxide, Hadacidin, Iodine, di-iodo-ethane, Isopropanol, Methy Difluoroacetate, Nitroethane, Nitroethanol, Nitrogen, Nitrogen Tetroxide, Nitrogen Trifluoride, Nitromethane, Nitropropane, Nitrobutane, Oxygen, Ozone, PMCPS, Tungsten Hexacarbonyl, Water, or Xenon Difluoride. Other gases are, however, are possible as well, for example methoxy acetylchloride, methyl acetate, methyl nitroacetate, ethyl acetate, ethyl nitroacetate, propyl acetate, propyl nitroacetate, nitro ethyl acetate, methyl methoxyacetate, and methoxy acetylchloride, Acetic acid or thiolacetic acid, Hexafluoroacetylacetone, silazane, trifluoroacetamide, dicobalt octacarbonyl, molybdenum hexacarbonyl, and combinations thereof.

Furthermore, dual beam system 91 further comprises a contact pin 981. Contact pin 981 is connected to a manipulator (not shown) for precise movement of the contact pin 981, for example under control of the charged particle beam 944 during an image acquisition. Thereby, structures present on the wafer surface can be contacted and electrically connected to control device 19.

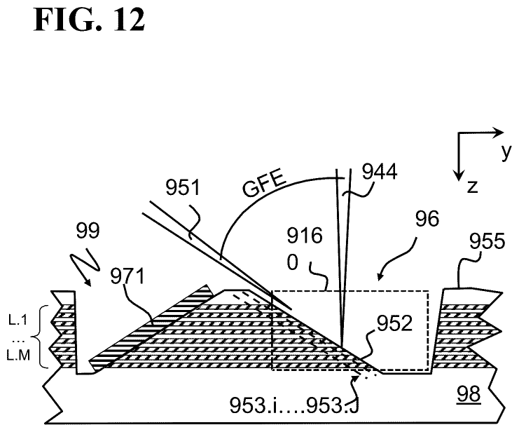

FIG. 10 illustrates the wedge cut geometry at the example of a 3D-memory stack like the one explained with reference to FIGS. 3A to 3C. FIG. 10 illustrates the situation, when the surface 952 is the new cross-section surface which was milled last by FIB 51. The cross-section surface 952 is scanned for example by SEM beam 944, which is in the example of FIG. 10 arranged at normal incidence to the wafer surface 955, and a high-resolution cross-section image slice is generated. The cross-section surfaces 953.1 . . . 953.N are subsequently milled with a FIB beam 951 at an angle GF of approximately 30° to the wafer surface 955, but other angles GF, for example between GF=20° and GF=60° are possible as well. The cross-section image slice comprises first cross-section image features, formed by intersections with high aspect ratio (HAR) structures or vias (for example first cross-section image features of HAR-structures 94.1, 94.2, and 94.3) and second cross-section image features formed by intersections with layers L.1 . . . L.M, which comprise for example SiO₂, SiN— or Tungsten lines. Some of the lines are also called “word-lines”. The maximum number M of layers is typically more than 50, for example more than 100 or even more than 200. The HAR-structures and layers extend throughout most of the volume in the wafer but may comprise gaps. The HAR structures typically have diameters below 100 nm, for example about 80 nm, or for example 40 nm. The cross-section image slices contain therefore first cross-section image features as intersections or cross-sections of the HAR structures at different depth (Z) at the respective XY-location. In case of vertical memory HAR structures of a cylindrical shape, the obtained first cross-sections image features are circular or elliptical structures at various depths determined by the locations of the structures on the sloped cross-section surface 952. The memory stack extends in the Z-direction perpendicular to the wafer surface 955. The thickness d or minimum distances d between two adjacent cross-section image slices is adjusted to values typically in the order of few nm, for example 30 nm, 20 nm, 10 nm, 5 nm, 4 nm or even less. Once a layer of material of predetermined thickness d is removed with FIB, a next cross-section surface 953.i . . . 953.J is exposed and accessible for imaging with the charged particle imaging beam 944. During repeated milling and imaging, a plurality of cross sections is formed, and a plurality of cross section images are obtained, such that an inspection volume 9160 of size LX×LY×LZ is properly sampled and for example a 3D volume image can be generated. Thereby, the damage to the wafer is limited to the inspection volume 160 plus a damaged volume in y-direction of length LYO. With an inspection depth LZ about 10 μm, the additional extension of the damage volume in y-direction is typically limited to below 20 μm.

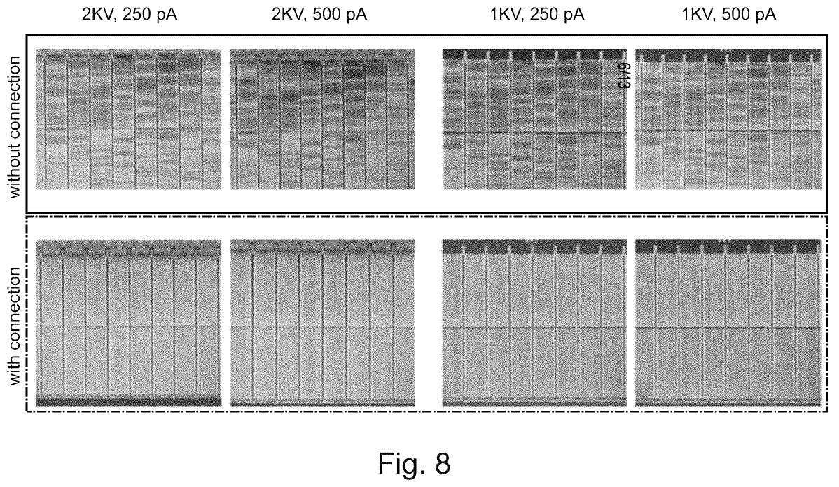

FIGS. 4A and 4B show example SEM measurements of an area of 3D NAND semiconductor structure as explained in FIGS. 3A-3C, where a wedge was prepared as an area to be examined as explained above, e.g. with the apparatus of FIG. 9. For further illustration, FIG. 5 schematically shows a further 3D NAND semiconductor structure sample 51, similar to the one shown in FIG. 10, where a wedge has been prepared by removing a part 50 along a wedge edge 50A, to provide an area to be examined. In case of FIG. 4A, edge 50A is parallel to slits 35, and in case of FIG. 4B edge 50A runs perpendicular to slits 35. In FIG. 4A, the image is uniform, whereas in FIG. 4B strong variations of the brightness occurs. These variations are due to charging by the electron beam of the SEM used, as in case of FIG. 4B the regions between slits 35 are electrically isolated due to the material removal shown in FIG. 5. Therefore, in case of FIG. 4B, the areas between the slits are identified as electrically isolated regions at step 11 of FIG. 1.

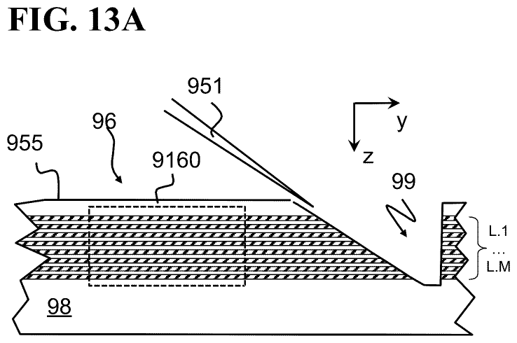

This charging is further illustrated in FIGS. 11A and 11B. FIG. 11A shows charges (symbolized by “-”) generated in layers L.1 . . . L.M of FIG. 10 caused by inspection with beam 944. When the imaging is repeated, charge may build up further, as illustrated in FIG. 11B, leading to further image deterioration.

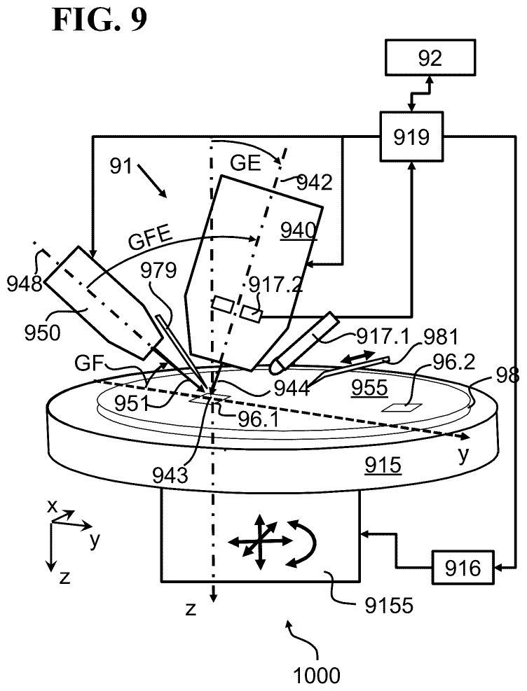

According to an embodiment, in case of a situation as in FIG. 4B with electrically isolated regions, an electrical connection is provided connecting the stripes. The effect will be shown referring to FIGS. 6A and 6B.

FIG. 6A shows an SEM image, where an area 60 to be examined is formed as a wedge as in FIG. 4A, i.e. with edge 50A of FIG. 5 perpendicular to slits 35. Here, as indicated by arrows 61, charge may flow through the stripes, for example through the wordlines, to the right and left of the area to be examined, where the stripes continue, and therefore charge may flow away from the area 60 to be examined. Here, no additional electrical connection is needed.

In contrast, in FIG. 6B the area to be examined is formed as in FIG. 4B, i.e. with edge 50A of FIG. 5 parallel to slits 35. In this case, due to the electrical isolation provided by slits 35, charge cannot flow to the sidewalls of the wedge formed, as indicated by a crossed out arrow 62. Moreover, due to the material removal charge also cannot flow in the downwards direction in FIG. 6B, as also indicated by a crossed out arrow 62.

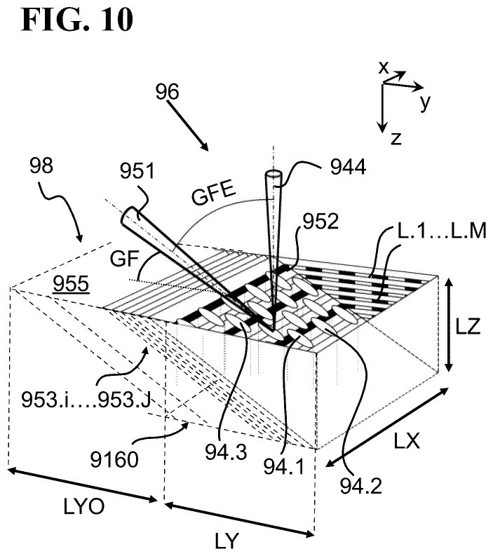

If no electrical connection is provided towards the top of FIG. 6B, therefore the charge cannot flow away from the area to be examined, leading to the effect shown in FIG. 4B. However, in step 12 in the example of FIG. 6B a grounding trench 64 is formed providing an electrical connection. An example formation is shown in FIGS. 7A and 7B, where a trench 70 is formed and then at least for partially filled by a conductive material 71 in FIG. 7B, for example a metal like platinum. Instead of a metal, for example also highly doped semiconductor material may be used to form an electrical connection.

In FIG. 6B, trench 64 filled with a conducting material provides a possibility for charge to flow from the area 60 to be examined away to a through trench 64. In the example of FIG. 6B, trench 64 couples the stripes to a reference potential like ground and/or to a substrate, thus enabling the charge to flow away. In other embodiments, the trench may only connect the stripes with each other, resulting in a balancing of the charges.

While a single trench filled with conductive material is described above, also a plurality of electrical connections, for example using a plurality of trenches, may be provided.

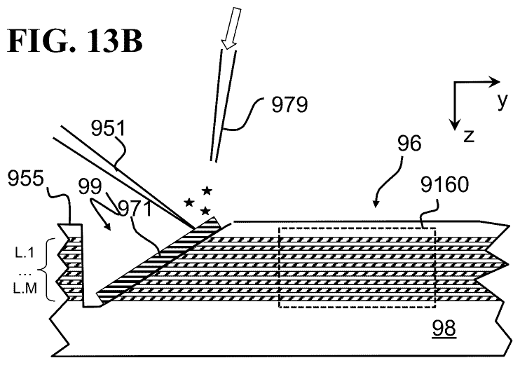

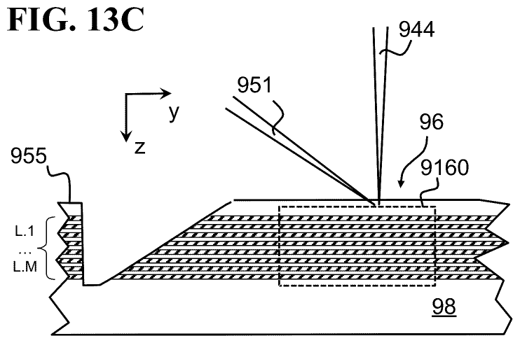

Examples for forming the electrical connection are further explained referring to FIGS. 12 and 13. In FIG. 12, an electrical connection 971 is provided by deposition of a metal or other electrically conducting material in a trench 99 on a further slanted surface, thus interconnecting all or some of layers L1 . . . L.M with each other. FIGS. 13A to 13C illustrate formation of electrical connection 971: FIG. 13A shows the formation of trench 99 using FIB 951, by ion beam milling similar to the preparation of the slanted surface 956 for the inspection.

FIG. 13B, which compared to FIG. 13A is rotated by 180°, shows deposition of electrical connection 971. Deposition may be performed using a particle beam 979 of a corresponding conducting material, e.g. a metal like platinum. The material may then be structured using FIB 951.

Returning to FIG. 1, after step 13 at step 14 SEM measurement of the area to be examined is performed. For a 3D tomography, step 13 may then be repeated by removing material and performing a further measurement. In embodiments, step 12 may be performed only once, providing electrical connections for all electrically isolated regions which may occur during preparation of the area to be examined. At step 15, the measurement may be then evaluated, for example in case of 3D NAND memories or other high aspect ratio structures as described in the already cited WO 2022/223 229 A1.

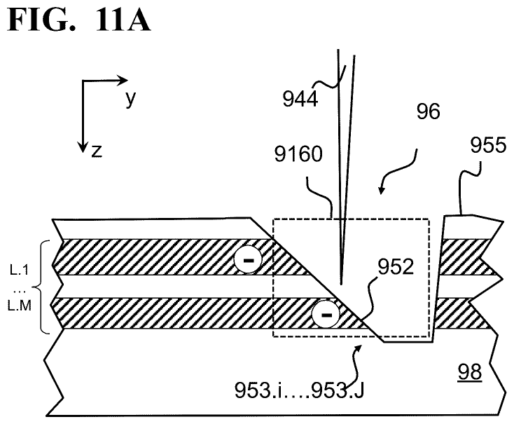

The effect of the providing of the electrical connections on the measurement is shown in FIG. 8 for various beam currents and acceleration voltages, the voltage being either 1 kV or 2 kV and the beam current either 50 pA or 500 pA. Without the electrical connection (top row) strong variations in brightness of the SEM measurement results, whereas with the electrical connection provided (bottom row) significantly lower brightness variations result.

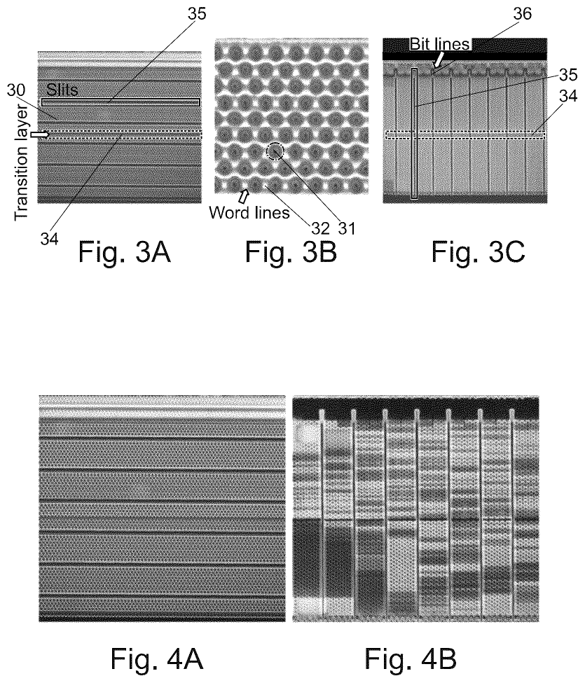

FIG. 2 illustrates another apparatus according to an embodiment, arranged for performing the methods discussed above. The system of FIG. 2 comprises one or more sample preparation devices 20, which for example perform steps 12 and 13 of FIG. 1, i.e. providing electrical connection for at least one electrically isolated region, and prepare the area to be examined. Such sample preparation devices may include conventional semiconductor manufacturing and analysis devices, like ion beam devices for trench formation, metal deposition chambers e.g. for depositing metal in a trench, gas injection systems (GIS) for precursor gases used in 3D pattern generation, SEM or other imaging devices for observation and supervision of the preparation process, lithography devices and the like, which are controlled by one or more controllers to perform the sample preparation discussed above. The thus prepared sample is then provided to a SEM 21 for SEM measurement. While in the embodiment of FIG. 9 inspection and sample preparation are performed in a single device 1000, FIG. 2 shows an example where the two are separated, showing that both possibilities exist.

Some embodiments are provided by the following examples:

Example 1. A method of preparing a sample for a charged particle beam imaging, comprising:
providing a semiconductor structure sample,
identifying at least one electrically isolated region in an area to be examined of the semiconductor structures sample, and
providing an electrical connection to the at least one electrically isolated region.

Example 2. The method of example 1, wherein the electrical connection is coupled to one of a reference potential or a substrate.

Example 3. The method of example 1 or 2, wherein the at least one electrically isolated region comprises a plurality of electrically isolated regions, and wherein the electrical connection electrically couples the plurality of electrically isolated regions with each other.

Example 4. The method of any of examples 1-3, wherein providing the electrical connection comprises providing a trench, and filling the trench at least partially with an electrically conducting material.

Example 5. The method of any one of examples 1-4, wherein the electrical connection is provided outside the area to be examined.

Example 6. The method of any one of examples 1-5, further comprising preparing the area to be examined, wherein the preparing of the area to be examined causes the formation of at least one of the at least one electrically isolated region.

Example 7. The method of example 6, wherein preparing the area to be examined comprises removing material from the semiconductor structure sample.

Example 8. The method of any one of examples 1-7, wherein the semiconductor structure sample comprises a NAND memory structure.

Example 9. The method of any one of examples 1-8, wherein identifying the electrically isolated regions is based on design data of the semiconductor structure sample.

Example 10. A method for inspecting a semiconductor structure sample, comprising: preparing a sample based on the semiconductor structure sample according to the method of any one of examples 1-9, and
performing a charged particle beam inspection of the prepared sample.

Example 11. A sample preparation device, configured to perform the method of any one of examples 1-10.

Example 12. A system comprising:
the device of example 11, and
a charged particle beam inspection device.

What is claimed is:

1. A method, comprising:
ion beam milling a semiconductor structure sample at an angle relative to a surface of the semiconductor structure sample to form a slanted surface and to form an electrically isolated region in an area of the semiconductor structure sample to be examined;
providing an electrical connection to the electrically isolated region; and
performing a charged particle beam inspection of the area of the semiconductor structure sample to be examined.

2. The method of claim 1, wherein the electrical connection is coupled to a reference potential or to a substrate.

3. The method of claim 1, wherein the electrically isolated region comprises a plurality of electrically isolated regions, and the electrical connection electrically couples the electrically with each other.

4. The method of claim 3, wherein:
before providing the electrical connection, the plurality of electrically isolated regions cause formation of a plurality of capacitances; and
providing the electrical connection merges the plurality of capacitances to a single capacitance.

5. The method of claim 1, wherein providing the electrical connection comprises providing a trench and disposing an electrically conducting material in the trench.

6. The method of claim 1, wherein the electrical connection is outside the area of the semiconductor structure sample to be examined.

7. The method of claim 1, wherein the semiconductor structure sample comprises a NAND memory structure.

8. The method of claim 1, further comprising identifying the electrically isolated region based on design data of the semiconductor structure sample.

9. The method of claim 1, further comprising:
repeating the ion beam milling to generate a further slated surface comprising a further area of the semiconductor structure sample to be examined; and
performing the charged particle beam inspection to inspect the further area of the semiconductor structure sample to be examined.

10. The method of claim 9, wherein the electrical connection is a connection to an electrically isolated region of the further area to be examined.

11. The method of claim 1, wherein:
the semiconductor structure sample comprises slits;
an edge between the surface of the semiconductor structure sample and the slanted surface is perpendicular to the slits; and
the electrically isolated region is between adjacent slits.

12. The method of claim 1, wherein the electrically isolated region comprises a plurality of electrically isolated regions, the electrical connection electrically couples the electrically with each other, and the connection is coupled to a reference potential or to a substrate.

13. A method, comprising:
removing material from a semiconductor structure sample at an angle relative to a surface of the semiconductor structure sample to form a slanted surface and to form an electrically isolated region in an area of the semiconductor structure sample to be examined;
providing an electrical connection to the electrically isolated region; and
performing a charged particle beam inspection of the area of the semiconductor structure sample to be examined.

14. An apparatus, comprising:
a focused ion beam device configured to ion beam mill a semiconductor structure sample at an angle relative to a surface of the semiconductor structure sample to form a slanted surface and to form an electrically isolated region in an area of the semiconductor structure sample to be examined;
a deposition device configured to provide an electrical connection to an electrically isolated region in the area of the semiconductor structure sample to be examined by electrically separating the electrically isolated region from conducting portions of the semiconductor structure sample; and
a charged particle beam inspection device configured to inspect the area to be examined.

15. The apparatus of claim 14, wherein the electrical connection is coupled to a reference potential or to a substrate.

16. The apparatus of claim 14, wherein the electrically isolated region comprises a plurality of electrically isolated regions, and the electrical connection electrically couples the electrically with each other.

17. The apparatus of claim 14, wherein the electrical connection comprises a trench and an electrically conducting material in the trench.

18. The apparatus of claim 14, wherein the electrical connection is outside the area of the semiconductor structure sample to be examined.

19. The apparatus of claim 14, wherein the semiconductor structure sample comprises a NAND memory structure.

20. The apparatus of claim 14, wherein:
the semiconductor structure sample comprises slits;
an edge between the surface of the semiconductor structure sample and the slanted surface is perpendicular to the slits; and
the electrically isolated region is between adjacent slits.
